(19) United States
(12) Patent Application Publication
(10) Pub. No.: US 2012/0267730 A1
(43) Pub. Date: Oct. 25, 2012

(54) MICRO-ELECTROMECHANICAL SYSTEM (MEMS) DEVICE

(75) Inventors: Stéphane RENARD, Champ sur Drac (FR); Antoine FILIPE, La Tronche (FR); Joël COLLET, Saint Martin d'Uriage (FR); François-Xavier BOILLOT, Grenoble (FR)

(73) Assignee: TRONICS MICROSYSTEMS S.A., Crolles (FR)

(21) Appl. No.: 13/451,367

(22) Filed: Apr. 19, 2012

(30) Foreign Application Priority Data
Apr. 20, 2011 (EP) 11 003 325.5

(51) Int. Cl. H01L 29/84; H01L 21/50

(52) U.S. Cl. 257/415; 438/51; 257/E29.324; 257/E21.499

(57) ABSTRACT

A micro-electromechanical system (MEMS) device for measuring accelerations, angular rates, or for actuation comprises at least two substrates and at least one movable structure arranged in a cavity between the substrates. An electrically conducting frame surrounding the movable structure is arranged at an interface of the two substrates. The frame is electrically separated from the movable structure and connected by at least first and second electrically conducting connections to the first and second substrates, respectively. The frame may have a width of not more than 150 preferably not more than 50 μm. The first connection is at an interface between the frame and the first substrate. The second connection is a layer applied at an outer periphery of the frame and a peripheral face of the second substrate. The structure keeps electrical fields and electromagnetic disturbances away from the sensor and may also be used for shielding micro-electronic circuits.

### TECHNICAL FIELD

The invention relates to a micro-electronic device, preferably a micro-electromechanical system (MEMS) device (e.g. a sensor for measuring acceleration or rotation speed or an actuator) comprising at least two substrates, at least one micro-electronic structure, preferably a movable structure in a MEMS-layer, wherein said micro-electronic structure is arranged in a cavity which is encapsulated between the at least two substrates. The invention also relates to a method for manufacturing such a device.

### BACKGROUND

### Prior Art

There is a wide range of MEMS devices for detecting accelerations e.g. U.S. Pat. No. 5,220,835 (Ford), U.S. Pat. No. 5,488,864 (Ford), U.S. Pat. No. 5,900,550 (Ford), U.S. Pat. No. 6,000,287 (Ford), U.S. Pat. No. 6,082,197 (Zexel), U.S. Pat. No. 6,308,568 (Murata). There are also sensor devices that are sensitive to accelerations in different directions.

U.S. Pat. No. 5,065,628 (Fraunhofer Gesellschaft) discloses a MEMS (Micro-ElectroMechanical System) device for measuring accelerations in several different directions. The accelerations are measured by three micromechanical sensors, each consisting of an inert mass (proof mass) that is sensitive to a motion in only one of the different directions e.g. x, y and z. The sensors are integrated in a single crystal surface layer.

Typically, a MEMS device comprises at least one movable structure such as a mobile mass or a mobile cantilever encapsulated in a cavity.

U.S. Pat. No. 5,623,099 (Temic Telefunken) shows a basic structure for packaging a capacitive acceleration sensor. Two semiconductor substrates are bonded together at their major surfaces by a thermally grown oxide. A cavity is formed between the two substrates for encapsulating a mobile mass sensing acceleration in one direction. Each substrate provides a part of the box-shaped cavity and the mobile element, which defines a variable capacity within the cavity, moves perpendicularly to the substrate. The thermally grown oxide provides an electrical insulation between the substrate plates.

U.S. Pat. No. 5,381,300 (Sextant Avionique) and U.S. Pat. No. 6,153,917 (Akebone Brake) propose an acceleration sensor that is made of three silicon plates welded together by an annealing process. Instead of using a single silicon oxide layer for bonding the substrates a sandwich consisting of first insulating layer, a conducting layer and a second insulating layer is applied. The sandwich structure avoids stray capacities influencing the measurements.

For multiple axes sensor devices, one of the key points is cross-axis sensitivity. The cross-axis sensitivity determines how much acceleration for an accelerometer (or rotation speed for a gyrometer), perpendicular to the measuring axis, couples to the output. Typically, cross-axis sensitivity should be not more than 1% and preferably substantially less than 1% on best performing devices, and less than 5% for low-performing devices.

### SUMMARY OF THE INVENTION

It is an object of the invention to provide a micro-electronic device, preferably a micro-electromechanical system (MEMS) device which is insensitive to electro-magnetic interferences. Preferably, the device should be adapted for integrating two or more movables structures or two or more micro-electric circuits (or combinations thereof) in a single chip. The chip may comprise a sensor and/or an actuator and/or an electronic circuit. It is a further object to reach electrical decoupling of separate devices (preferably of different sensors or actuators or electronic circuits) arranged in close proximity by a minimum consumption of substrate area. It is a further object of the invention to provide a process for manufacturing such a device.

According to the invention, the above mentioned objectives are achieved by a micro-electronic device, preferably a MEMS device comprising:
a) at least two substrates;
b) a micro-electronic structure, preferably at least one movable structure in a MEMS-layer;
c) wherein said micro-electronic structure, preferably said movable structure is arranged in a cavity which is encapsulated between the at least two substrates;
d) an electrically conducting frame surrounding said micro-electronic structure, preferably said movable structure and arranged at an interface of the two substrates,
e) wherein the frame is electrically separated from said micro-electronic structure, preferably form said movable structure; and
f) electrically connected by at least a first and a second electrically conducting connection to said frame and said first and second substrates, respectively,
g) and in that the first and second substrates and the frame all have a sufficient bulk conductivity to form a Faraday cage.

The method for manufacturing such a device comprises the steps of:
a) providing at least two substrates forming a cavity for a movable structure,
b) providing at least one micro-electronic structure, preferably a movable structure in a MEMS-layer, said micro-electronic structure being provided in the cavity,
c) providing an electrically conducting frame at an interface of the two substrates and the frame surrounding the micro-electronic structure, preferably the movable structure,
d) wherein said substrates and the frame all have a sufficient bulk conductivity to form a Faraday cage,
e) bonding the two substrates and the conducting frame together for encapsulating the micro-electronic structure in the cavity, wherein the frame surrounds the micro-electronic structure and the frame is electrically separated from said micro-electronic structure inside said frame,
f) providing a first and a second electrically conducting connection between said frame and said first and second substrates, respectively.

In the framework of the present invention a “micro-electronic” device is meant to be a general term encompassing “micro-electromechanical systems (MEMS)” as well as “micro-electronic circuits”.

According to the invention a substrate may be a single or multi-layer body that can be handled and processed as a self-containing element and that can be bonded face-to-face to the other substrate in the course of a bonding step. Each substrate of the invention may be a single unit or may consist of two substrates or may be a layered element such as an SOI (Silicon On Insulator) structure or an element coated with thin layers. All these types of substrates are known in the prior art (see also introductory chapter “background, prior art” of this specification). Typically the substrates mainly consist of a semiconductor material such as crystalline silicon defining the bulk material of the substrate. The outer surface of the substrate (i.e. the surface that is not at the interface to the frame and not inside the cavity) should have a resistance less than 5 Ohm in order to enable the Faraday cage effect. With typical thickness of several 100 μm, preferably in the range of 300-450 μm, this is leading to a resistivity less than 50 mOhm×cm.

In the framework of the present invention, a movable structure comprises a mobile mass or a mobile cantilever supported by a flexible suspension element at a distance to the walls of the cavity. The movable structure may therefore oscillate or rotate about one or more geometric axis (x, y, z) or may be deflected from a still (inactive) position by electrostatic forces. The movement of the mobile element may be initiated by inertial forces or by electrical fields. According to the invention, the movable structure is implemented in a MEMS layer. The MEMS layer may be a separate substrate or may be formed on top of one of the two substrates.

The electrically conducting frame is at an interface between the two substrates. It defines a substantially closed ring or hedge around the movable structure in the MEMS-layer. In the top plan view, the ring or hedge may have a rectangular shape or any polygonal shape running around the movable structure.

The electrically conducting frame is part of a so-called Faraday cage formed by the two substrates and the frame. The Faraday cage does not have to be perfectly closed in order to perform the intended electromagnetic shielding effect. It is to be remembered that the electromagnetic shielding affect of a Faraday cage may also be achieved by a mesh-type structure, meaning that a local opening in the Faraday should not be a problem as long as its typical dimension is less than the wavelength of the electromagnetic field (i.e. less than 300 μm for a frequency of 1 THz). Such openings may be necessary for electrically contacting the mobile structure or the electrodes inside the cavity from outside of the Faraday cage.

Generally speaking, the proposed structure has the effect of a Faraday cage keeping electrical stray fields and electromagnetic disturbances away from the movable structure inside the cavity and from the electrical measurements and/or from electrical control elements inside the cavity. Preferably, by using an electrically conducting wafer sealing (such as a metallic sealing) it is possible to use a seal width as low as 30 μm Therefore, it is possible to ensure a perfect seal around each movable structure (which may comprise a proof mass or a cantilever switch) and to achieve (if desired) multi-movable structures with minimum cross-axis sensitivity by a minimum amount of substrate area.

Indeed, according to the prior art the standard seal between active wafer and cap wafer is performed with glass-frit technology, with a thickness of 5 μm and a width of around 200 μm (micron). Implementing a Faraday cage around each sensor has a huge impact on the die area and can decrease the cost of the MEMS devices (e.g. sensors or actuators) very substantially.

The invention results in devices that have higher performance and that can also be used in harsh environment (with a lot of electromagnetic perturbations), such as in automotive applications, without sacrificing die area, i.e. unit cost.

### MEMS-Layer:

Optionally, the frame is part of the same MEMS-layer as the movable structure inside the cavity. This has the advantage that the production of the frame does not need an additional step in the production process. The MEMS-layer is typically made of silicon, preferably of mono crystalline silicon.

### Material and Width of Frame:

Optionally, the frame consists of crystalline silicon that is sufficiently high doped for achieving an adequate conductivity. The conductivity may be in the range of e.g. 10-20 mOhm×cm. The frame may have a width in a direction parallel to a main surface of the substrate of not more than 150 μm (micron). From the point of view of mechanical stability the width of the frame should be not less than 50 μm (micron). This provides sufficient mechanical stability during handling of the MEMS layer. An optimal range of the frame width for silicon structures is 50-150 μm (micron)

It is also possible to use a different material for the frame. For example, if the MEMS structure is not made from crystalline silicon, it may be advantageous not to use crystalline silicon for the frame but to use the same material as the MEMS structure. Of course, it is not mandatory to make the frame from the same material as the MEMS structure.

The width of the frame (i.e. of the beams of the frame) may be as small as possible to save die area. However, under certain conditions the width may also be above 50 or above 100 μm when the conductivity of the frame material is only moderate or if the metal sealing technology requires a larger area.

### Thickness of Frame:

Optionally, the frame has a thickness (measured in a direction normal to the surface of the substrate, i.e. z-direction) that is within a thickness range defined by the mobile mass of the sensor. This means that the frame may be produced from the same layer as the mobile mass of the MEMS structure. For instance, the frame may be etched into the silicon layer at the periphery of the MEMS structure.

However, it is also possible to use the invention in combination with any type of mobile mass, in particular with a mobile mass that is not on the same level as the frame.

Connection Between Frame and First Substrate:

Optionally, there is a first electrically conducting connection at the interface plane between the frame and the first substrate. Said interface plane substantially corresponds to the plane of the main surface of the substrate. Metal stripes placed on the main surface of the first substrate may form the conducting connection and ensure the electrical contact between the first substrate and the frame. In the top plan view, the stripes are quasi buried under the frame. The stripes may define a closed rectangle or polygon line surrounding the MEMS structure of a sensor in the same way as the frame does.

Alternatively, the conducting connection between the first substrate and the frame may also be placed at the outside periphery of the frame. Further more, the conducting connection does not have to be formed as continuous metal stripes that are so to speak a foot-print of the shape of the frame. Electrical sealing may also be achieved by several separate contacting elements (contact pads).

### Connection Between Frame and Second Substrate:

Optionally, the second electrically conducting connection is provided by a conducting layer applied at the outer periphery of the frame and at a peripheral face of the second substrate. The peripheral face is a surface that is orthogonal to or inclined to the main face i.e. the x-y-face of the substrate. This connection is therefore not interposed between the mating main surfaces of the second substrate and of the frame. Rather more, it is arranged at the periphery of the device (i.e. outside the area of the frame) for electrically connecting the frame and the substrates to ground voltage.

Alternatively, it is possible to use a similar connection as described between the frame and the first substrate.

Inclined Peripheral Face:

Optionally, the peripheral surface of the second substrate has a section that is inclined at an angle of <90° with respect to the main surface of the substrate. The electrical connection is applied to the inclined section of the peripheral surface and to the peripheral face of the frame.

Nevertheless an alternative solution is to avoid usage of the above mentioned connection in order to save die surface. Of course in this case the Faraday cage surrounding the cavity containing the movable structure is not completely closed in terms of conductivity, but the gap of isolation is so small that the interferences are sufficiently small.

### Insulating Layer Between Frame and Second Substrate:

Optionally, the frame and the second substrate are connected (or bonded) at their mating main surfaces by an insulating bonding material, preferably by an oxide. This insulating layer may also be used to electrically isolate the MEMS structure (mobile mass, cantilever etc.) from the top substrate defining the cavities of the device. Alternatively, the insulating layer may also be an oxide layer. The bonding material may also be a polymer or a silicon or glass fit,

### Third Substrate:

Optionally, the mobile mass and the frame are integrated in a third substrate, which is interposed between the first and the second substrate. The device may then consist of three substrates: The first and/or the second substrates are provided with cavities in the area where the third substrate has its mobile mass. So the mobile mass can move according to the acceleration applied or according to electromagnetic fields deflecting the movable structure.

### Separation Space

Optionally, the frame and the MEMS structure are separated by a separation space (a trench in the MEMS layer, or a slot). This trench may define (in a top plan view of the frame) a rectangle or a polygon line running around the MEMS structure and it provides for electrical isolation. The separation space may be as narrow as a few microns (in a direction parallel to the surface).

In the z-direction (i.e. perpendicular to the surface of the substrate) the trench penetrates the MEMS layer completely.

Alternatively, the electrical isolation may be achieved by areas of non-conducting material between the frame and the MEMS structure.

### Multiple Axis Acceleration Detection:

Preferably, the device comprises two or more movable structures arranged side by side in close proximity. The frame surrounds the two or more movable structures and has a separating section (i.e. a separating beam) arranged between the movables structures. So the movable structures are electrically isolated form each other and from further external influences. Three movables structures may be arranged in one row, in a square area or rectangular area encompassing the movables structures. Other arrays are also possible, but they might be less efficient in using the available chip area.

### Acceleration Sensor.

Preferably the device is an acceleration sensor integrated in at least one of said at least two substrates. The patents U.S. Pat. No. 5,220,835 (Ford), U.S. Pat. No. 5,488,864 (Ford), U.S. Pat. No. 5,900,550 (Ford), U.S. Pat. No. 6,000,287 (Ford), U.S. Pat. No. 6,082,197 (Zexel), U.S. Pat. No. 6,308,568 (Murata), U.S. Pat. No. 5,377,544 (Motorola) show linear acceleration sensors and the patents EP 0 623 807 A1 (GM), U.S. Pat. No. 5,329,815 (Motorola) show rotation rate sensors. The whole variety of designs may be used for the movable structure. However, the invention is not limited to the designs shown in those patents.

Multi-Axis Sensor:

Optionally, the movable structures of a multi-axis device are sensitive to mutually different directions. Each movable structure is sensitive to only one acceleration direction. Combining three single-axis movable structures, each being sensitive to only one of the directions x, y and z, results in a most preferred embodiment.

It is also possible to use the frame in combination with rotation rate MEMS sensors. One or more of the movable structure may also be sensitive to a rotation (gyro) or to other type of physical variable that can be detected by capacitive measurements.

The device may also be an actuator, e.g. a switch. The movable structure may be a cantilever that is attracted to an electrode for making contact. When the attracting electrical field is removed, the cantilever moves back to its still position.

Movement Detection Electrodes:

Preferably, the first substrate comprises electrodes for detecting a movement of the mobile mass. The second substrate is then only a cap for protecting the MEMS structure. If the MEMS structure is an actuator there are control electrodes for changing the position of the cantilever element (still position vs. deflected position). The invention does not propose new electrode structures but refers to well known prior art electrode structures.

The method for manufacturing the device may involve one or more of the following steps.
forming the conducting frame and the movable structure in a common MEMS layer.
interposing a third substrate at the interface between the first and the second substrate, said third substrate comprising the movable structure and the frame;
etching a trench (separation space) into the third substrate for separating the frame from the sensor;
etching the peripheral face of the second substrate to generate an inclined section;
depositing a metal layer bridging the inclined peripheral face and the frame;
bonding the frame and the second substrate at their mating main surfaces by an insulating bonding material, preferably by a silicon direct bonding (SDB). Alternatively, a eutectic/thermo compression bonding may be used for bonding the substrates one to another.

Silicon direct bonding is a method well known in the art (see e.g. U.S. Pat. No. 7,442,622). The following detailed description and the combination of all claims present further advantageous embodiments and element combinations of the invention.

Any optional element that has been explained in relation to the MEMS system may also be used in combination with an electronic circuit in place of the movable structure.

### BRIEF DESCRIPTION OF THE DRAWINGS

The accompanying drawings further illustrate the invention and serve to explain the preferred embodiments in combination with the detailed specification:

FIG. 1a, b a schematic representation of a device with two movable structures arranged side by side;

FIG. 2a-c a schematic cross-section of a device with two movable structures in more detail;

FIG. 3 a schematic top plan view of a frame arrangement on a wafer,

FIG. 4 a further variant of a frame,

FIG. 5 a device with a T-shaped z-axis sensor.

FIG. 6 a schematic cross-section of a device with two micro-electronic circuits (section B-B of FIG. 7);

FIG. 7 a schematic plan view of along line A-A of FIG. 6.

Generally speaking, like reference numerals refer to identical parts.

### PREFERRED EMBODIMENTS

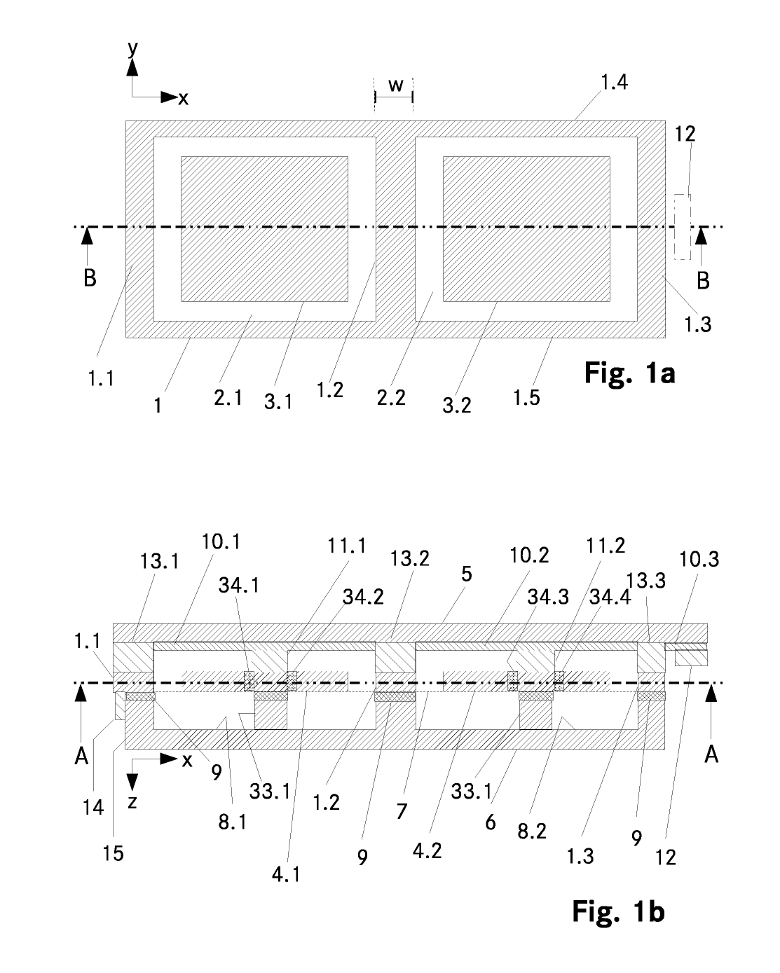

FIG. 1a, b illustrate a possible embodiment of the invention. FIG. 1a is a cross-section along the line A-A shown in FIG. 1b and FIG. 1b is a cross-section along the line B-B in FIG. 1a. A frame 1 having a rectangular shape with for outer sections 1.1, 1.3, 1.4, 1.5 and an intermediate section 1.2 defines two separate free areas (windows). There is a sensor 3.1, 3.2 in each of said free areas. The sensors 3.1, 3.2 are implemented in MEMS technology. They each comprise a mobile mass for sensing the acceleration exerted on the device. The sensors 3.1, 3.2 are e.g. single axis sensors of a known structure (see background of the invention). They may detect e.g. x- and y-axis accelerations. The sensors 3.1, 3.2 are separated by a separation space 2.1, 2.2 from the frame 1. The beam section 1.2 of the frame separates the two sensors 3.1, 3.2 from each other.

The frame may have a width w (measured in x-direction) of the section 1.2. of e.g. 50 μm (micron). The sections 1.4 and 1.5 may have a different width (measured in y-direction). The same is true for the sections 1.1 and 1.3.

As shown in FIG. 1b the frame 1 is on the same level in z-direction as the mobile masses 4.1, 4.2 of the sensors 3.1, 3.2. In fact, they are made from the same substrate 7. Substrate 7 corresponds to the MEMS layer (active layer). The frame 1 is connected to the third substrate 7, which is sandwiched between a first substrate 5 and a second substrate 6. So the third substrate 7 is forming the interface between first substrate 5 and second substrate 6. All three substrates 5, 6, 7 are preferably made of crystalline silicon.

The frame 1 is attached to the second substrate 6 by an insulating bonding layer 9 (e.g. silicon dioxide). The bonding layer 9 substantially covers all sections 1.1-1.5 of the frame 1. In the top plan view the area of the bonding layer 9 corresponds to the top plan view of the area of the frame 1 shown in FIG. 1a. The second substrate 6 has two cavities 8.1, 8.1, one for each mobile mass 4.1, 4.2. The mobile masses 4.1, 4.2 are supported at the distance from the ground plane of the cavity 8.1, 8.2 e.g. by a central post 33.1, 33.2. The mobile mass 4.1, 4.2, which may surround the central post 33.1, 33.2, is connected via a flexible suspensions 34.1, . . . , 34.4 to the central post. The flexible suspensions may have a known shape and structure and is not shown in detail in FIG. 1b. The first substrate 5 is covered with an insulating layer 10.1, 10.2 in the area below the mobile mass 4.1, 4.2.

The MEMS structures of substrate 7 are connected to driving and sensing electrodes 12 arranged at the outside of the device on insulating layer 10.3 of substrate 5 via metallic sealing 11.1, 11.2. The details of the electrode configuration and the conductor path between the metallic sealing 11.1, 11.2 and the driving and sensing electrodes 12 are not shown, but can be implemented as known in the prior art. The invention is not directed to those details.

The frame 1 (in FIG. 1b: sections 1.1-1.3) are electrically connected to the substrate 5 by metallic sealing 13.1-13.3. It is to be noticed that there is no insulating layer 10.1-10.3 in the area of the metallic sealing 13.1-13.3. So there is a direct electrical connection between the frame 1 and the bulk material of the substrate 5. The metallic sealing 13.1-13.3 has a geometric shape in the top plan view that is similar to the shape of the frame 1 (see FIG. 1a).

In order to establish an electrical connection between the frame 1 and the substrate 6 there is a metallic pad 14 at the peripheral face 15 bridging the non-conducting bonding layer 9 between the main face of the substrate 6 and the frame 1. In FIG. 1b the metallic pad 14 is placed just on one end of the device (opposite to the side with the electrodes 12). However, the metallic pad 14 may also extend to the sections 1.4 and 1.5 (and even to section 1.3) of the frame (see FIG. 1a).

The cavities 8.1, 8.2 shown in FIG. 1b are completely closed between the substrates so that the MEMS structure is encapsulated. According to the invention, the sensors 3.1, 3.2 are shielded from external stray fields and electromagnetic interference by a Faraday cage. This cage is implemented by the substrates 5 and 6 and by the frame 1, which all have a sufficient bulk conductivity (e.g. at least 1 mOhm×cm, preferably 10-20 mOhm×cm), and which are electrically connected with one another by metallic sealing 13.1-13.3 and by he metallic pad 14.

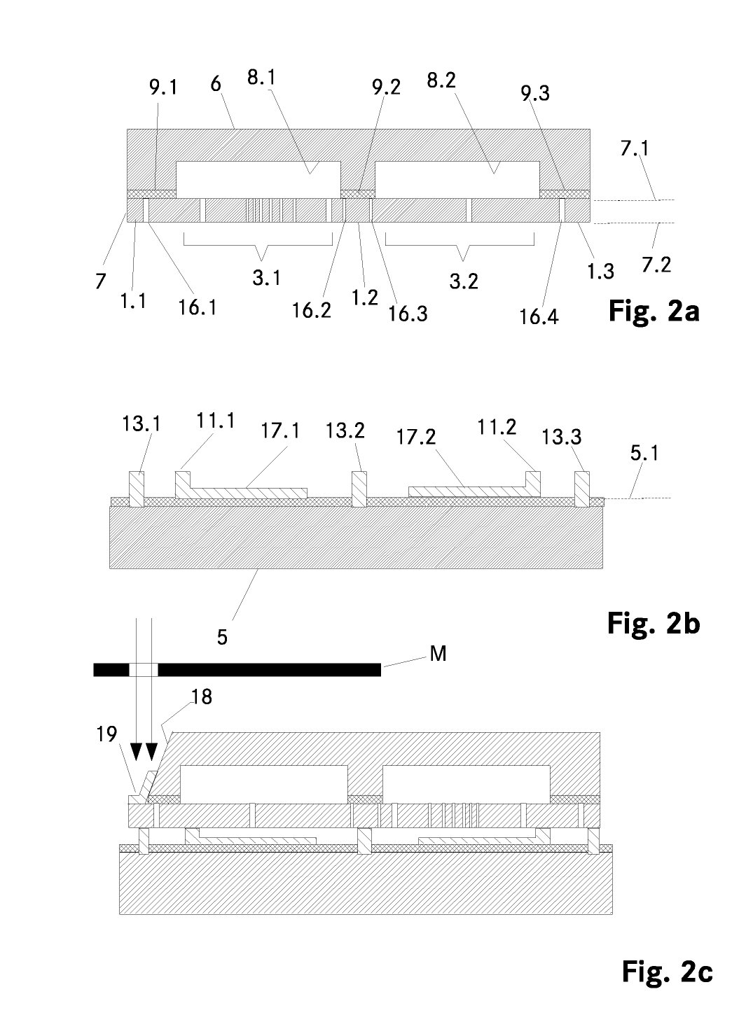

FIG. 2a-c illustrate a preferred method of manufacturing the device of the invention. FIG. 2a shows a SOI-structure (silicon on insulator) representing the second and third substrate 6, 7 shown in the schematic diagram of FIG. 1b. The main surface 7.1 of the substrate 7 is bonded to the opposing main surface of the substrate 6, which is covered by the oxide layer 9.1, 9.2, 9.3. The structure etched into the SOI-structure corresponds to first and second sensor 3.1, 3.2 and to the frame 1 (sections 1.1, 1.2 etc.). The fact, that the sensors 3.1 and 3.2 are oriented in different directions is schematically indicated in FIG. 2a by differently arranged penetrations (trenches) in the sensor area of substrate 7. The details of the support of the movable mass and of the flexible suspension are not shown as they are not relevant for the present invention.

The frame sections 1.1-1.3 are separated from the MEMS structure of the sensors 3.1, 3.2 by narrow slots or trenches 16.1-16.4. The trenches 16.1 und 16.2 correspond to the separation space 2.1 of FIG. 1a and the trenches 16.3 und 16.4 correspond to sections of the separation space 2.2 of FIG. 1a. It is evident from FIG. 2a that the trenches 16.1, . . . , 16.4 are placed outside the cavities 8.1, 8.2 and that the MEMS structure is therefore supported on the rim encompassing the cavities 8.1, 8.2.

FIG. 2b shows the substrate 5 carrying the electrodes 17.1, 17.2 for detecting the movement of the mobile mass of the MEMS structure. The metallic sealings 11.1, 11.2 are placed at the position where the MEMS structure needs to be contacted. In FIG. 2b the position is somewhat close to the trench 16.1 and 16.4, respectively. The metallic sealing 13.1, 13.2, 13.3 is placed directly on the substrate 5 at an area directly opposite to the frame sections 1.1, 1.2, 1.3.

FIG. 2c shows the device after bonding the two substrates 5 and 7 at their mating main surfaces 5.1 and 7.2 along the metallic sealings 13.1, 13.2, 13.2, 11.1, 11.2. The peripheral face 18 has been etched in the area of the frame 1 to get an inclined face. A metal layer may then be deposited through a mask M to provide the electrical contact between the frame and the top substrate 6.

The preferred embodiments illustrate the following three measures:
1. At the level of the MEMS structures design, a surrounding frame is designed around each MEMS structure that is etched in the active layer. The MEMS structures are (partially) above a cavity, which enables the mechanical movement. The decoupling frame is clamped or fixed to the substrate. It is usually insulated by a dioxide layer.
2. At the cap and interconnection level, an electrical connection of this frame is implemented, independent of the connections to the different parts of the MEMS structures. The connection is realized during the wafer bonding process through the metallic sealing. The electrical path connects the decoupling frame 1 to ground voltage, which is also the voltage of the substrate of the capping wafer.
3. And, finally, the substrate of the active wafer (MEMS) is connected to the ground voltage. This requires some additional technological steps because the substrate is normally insulated from the active MEMS layer by the embedded oxide layer of the SOI structure. As an example, the substrate, and the embedded oxide layer of the active wafer, can be chemically etched, locally, on the edge of the chip, above the decoupling frame, and then, a thick metallic layer can be deposited, through a mechanical shadow mask, in order to cover at the same time, the part of the active layer (at the frame level) which has been uncovered by the etching of the embedded oxide layer, and the edge of the etched part of the substrate.

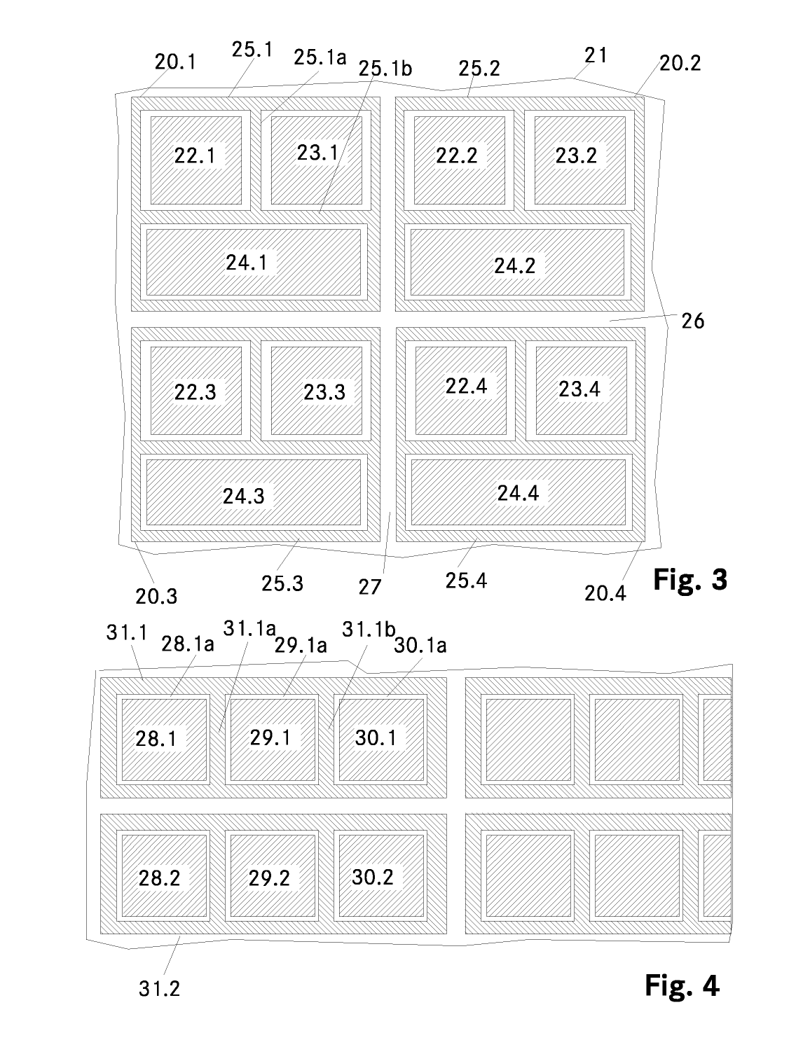

FIGS. 3 and 4 show further embodiments having a different geometric array of sensors. FIG. 3 represents a top plan view of a part of a wafer 21 with a regular array of devices 20.1, . . . , 20.4 detecting acceleration in 3 axes. Each of the devices 20.1, . . . , 20.4 consists of three single-axis sensors namely an x-axis sensor 22.1, . . . , 22.4, a y-axis sensor 23.1, . . . , 23.4 and a z-axis sensor 24.1, . . . , 24.4. In the example of FIG. 3 the x- and y-axis sensors 22.1, . . . , 22.4 and 23.1, . . . , 23.4 use the same amount of chip area, while the z-axis sensor 24.1, . . . , 24.4 needs more area. The x- and y-axis sensors 22.1, 23.1 have a square shape and are arranged in a row along the side of the z-axis sensor 22.3, which has a rectangular area of about the same length as the two other sensors 22.1, 23.1. Each device 20.1, . . . , 20.4 also comprises a frame 25.1, . . . , 25.4 according to the invention. The frame 25.1 separates the sensors 22.1, 23.1, 24.1 by beam like sections 25.1a, 25.1b. The devices 20.1, . . . , 20.4 are separated by trenches 26, 27 for cutting the wafer into chips. The contact electrodes for contacting the drive and sensing electrodes are not shown in FIG. 3.

FIG. 4 shows an array where each device comprises 3 single-axis sensors 28.1, 29.1, 30.1 and 28.2, 29.2, 30.2 arranged in a line. In this example the areas of the individual sensors 28.1, 29.1, 30.1 are shown to use the same amount of chip area. The frame 31.1, 31.2 has quasi three rectangular windows in a row and each window is occupied by a sensor 28.1, 29.1, 30.1 and 28.2, 29.2, 30.2 respectively, leaving a slot (having the shape of a rectangle in the top plan view of FIG. 4) between each sensor and the surrounding frame 31.1. The frame 23.1 separates the sensors 28.1, 29.1, 30.1 by beam like sections 31.1a, 311b, the separating sections of the frame having a T-shape (in the top plan view).

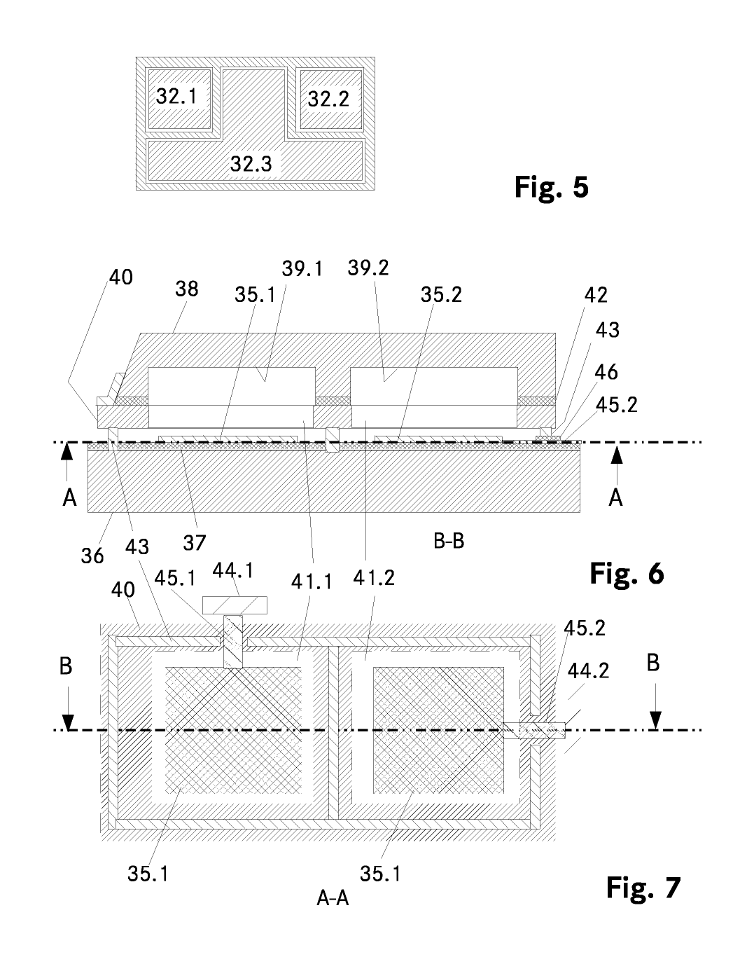

FIG. 5 shows a preferred embodiment of an acceleration detection device. The x- and y-axis sensors 32.1 and 32.2 have a square-type shape while the z-axis sensor 32.3 has a T-shape in the top plan view (i.e. in the z-directional view). The x- and y-axis sensors 32.1, 32.2 are arranged at each side of the T-shape of the z-axis sensor 32.3, so that the overall area occupied by the three sensors 32.1, 32.2, 32.3 has a rectangular shape. The z-axis sensor may have a mobile mass that is supported by a central post (not shown) as disclosed by the prior art mentioned in the introduction of this specification (U.S. Pat. No. 4,736,629; U.S. Pat. No. 5,404,749 etc.).

FIGS. 6 and 7 shows a further embodiment of the invention. Instead of a MEMS system with a movable structure there are two electronic circuits 35.1, 35.2 on a substrate 36. The electronic circuits are electrically isolated from the bulk of the substrate 36 e.g. by a insulation layer 37. The electronic circuits 35.1, 35.2 may be ASICs (e.g. a processor, a data communication circuit a sensor control circuit and) are not shown in detail.

A cap wafer substrate 38 is fixed on top of the substrate 36 and forms for each electronic circuit 35.1, 35.2 a cavity 39.1, 39.2. A silicon frame 40 is bonded to the cap wafer substrate 38 and has two openings 41.1, 41.2 aligned with the cavities 39.1, 39.2 and having the same size as the cavities 39.1, 39.2. The openings 41.1, 41.2 are larger than the area of the electronic circuits 35.1, 35.2 so that there is no mechanical or electrical contact between the frame 40 and the electronic circuits 35.1, 35.2. The bonding layer 42 between the frame 40 and the cap wafer substrate 38 may be an insulator. In fact, the frame 40 may be implemented on the substrate 38 in the manner of a SOI (silicon on insulator) structure.

The frame 40 and the substrate 36 are electrically connected by a metallic sealing 43. The metallic sealing 43 forms a closed line around each electronic circuit 35.1, 35.2. Only at local spots, where there is an electric connection 45.1, 45.2 from the electronic circuit 35.1, 35.2 to an electrode pad 44.1, 44.2 arranged outside of the frame 40, is there a small opening in the Faraday cage structure. To electrically separate the electric connection 45.1 from the frame 40 and the sealing there is e.g. a thin insulating layer 46 between the electric connection 45.1 and the metallic sealing 43.

The electric connection between the structure (e.g. mobile mass, electronic circuit) inside the cavity and the contact pad at the outside and in particular the manner in which the Faraday cage is made around this local electrical opening may be the same for MEMS structure and for electronic circuits. Accordingly, the details shown in FIG. 6, 7 may be also used for the embodiments shown in FIG. 1-5.

The invention is not limited to the embodiments shown in the drawings. The geometric arrangement of the sensors depends on the characteristics of the sensors (required chip area, particular two-dimensional shape, place of contact electrodes etc.) and on the desired efficient use of die area. Instead of using SOI-technology for providing the MEMS structure with cavities below the mobile masses it is also possible to use other techniques that require only one substrate instead of two. The invention can be applied to many different movable structures e.g. as shown in the prior art cited in the “Background, prior art” section of this specification. The movable mass may also be an actuator e.g. an RF switch (see (see e.g. U.S. Pat. No. 7,501,911).

While it is preferable that each movable structure is in a separate cavity which is protected by a Faraday cage structure according to the invention, it is also possible to have two movable structures within the same cavity. More generally speaking, the invention can be applied whenever a cavity on a microelectronic level has to be shielded against external electromagnetic fields.

The external metal layer for electrically connecting the frame may be arranged on one or several spots along the connection between the second and third substrate. It may also be a continuous line around the frame.

In summary, the invention provides a technical solution to minimize electrical interference between adjacent sensors or actuators.

1. A micro-electronic device, preferably a micro-electromechanical system (MEMS) device comprising
a) at least two substrates (5, 6),
b) a micro-electronic structure, preferably at least one movable structure in a MEMS-layer,
c) wherein said micro-electronic structure, preferably said movable structure (4.1, 4.2) is arranged in a cavity (8.1, 8.2) which is encapsulated between the at least two substrates (5, 6, 7),
d) an electrically conducting frame (1) surrounding said micro-electronic structure, preferably said movable structure (3.1, 3.2) and arranged at an interface of the two substrates (5, 6),
e) wherein the frame (1) is electrically separated from said micro-electronic structure, preferably form said movable structure (3.1, 3.2), and
f) the frame is electrically connected by at least a first and a second electrically conducting connection (13.1, 13.2, 13.3; 14) to said first (5) and second substrate (6), respectively,
g) wherein the first and second substrates and the frame all have a sufficient bulk conductivity to form a Faraday cage.

2. The device according to claim 1, wherein the frame (1) is part of the MEMS-layer.

3. The device according to claim 1, wherein the frame (1) consists of silicon and has a width (w) in a direction parallel to a main surface of the substrate (6) of not more than 150 μm (micron), preferably not more than 50 μm (micron).

4. The device according to claim 1, wherein the first electrically conducting connection (13.1, 13.2, 13.3) is at an interface plane between the frame (1) and the first substrate (5).

5. The device according to claim 1, wherein the second electrically conducting connection is a layer (14) applied at an outer periphery of the frame (1) and a peripheral face (15) of the second substrate (6).

6. The device according to claim 5, wherein the peripheral surface (18) of the second substrate (6) has a section that is inclined at an angle of less than 90° with respect to the main surface and wherein the conducting layer (19) is applied to the inclined section of the peripheral surface (18).

7. The device according to claim 6, wherein the frame (1) and the second substrate (6) are connected at their mating main surfaces by an insulating bonding material (9).

8. The device according to claim 7, wherein the frame (1) and the movable structure are separated by a separation space (2.1, 2.2).

9. The device according to claim 1, comprising two or more movable structures (22.1, 23.1, 24.1) arranged side by side, wherein the frame (25.1) surrounds the two or more movable structures (22.1, 23.1, 24.1) and has a separating section (25.1a, 25.1b) arranged between the movable structure (22.1, 23.1, 24.1).

10. The device according to claim 1, wherein the movable structure is an inertial mass responsive to acceleration.

11. The device according to claim 10, wherein the two movable structures are detection elements of sensors (3.1, 3.2) that are sensitive to mutually different directions, preferably to at least two of the directions x, y and z.

12. The device according to claim 1, wherein the first substrate (5) comprises electrodes (17.1, 17.2) for detecting or activating a movement of the movable structure (4.1, 4.2).

13. Method for manufacturing the device of claim 1 comprising the steps of:
a) providing at least two substrates (5, 6, 7) forming a cavity (8.1, 8.2)
b) providing at least one micro-electronic structure, preferably a movable structure in a MEMS-layer, said micro-electronic structure being provided in the cavity (8.1, 8.2),
c) providing an electrically conducting frame (1) at an interface of the two substrates and the frame surrounding the micro-electronic structure, preferably the movable structure (3.1, 3.2),
d) wherein said substrates and the frame all have a sufficient bulk conductivity to form a Faraday cage,
e) bonding the two substrates and the conducting frame together for encapsulating the micro-electronic structure (4.1, 4.2) in the cavity (8.1, 8.2), wherein the frame (1) surrounds the micro-electronic structure (3.1, 3.2) and the frame (1) is electrically separated from said micro-electronic structure (3.1, 3.2) inside said frame (1),
f) providing a first and a second electrically conducting connection between said frame and said first and second substrates, respectively.

14. Method according to claim 13, comprising the step of forming the conducting frame and the movable structure in a common MEMS layer.

15. Method according to claim 13, comprising the step of interposing a third substrate (7) between the first and the second substrate (5, 6), said third substrate (7) comprising the movable structure (4.1, 4.2) and the frame (1).

16. Method according to claim 14, comprising the step of etching a trench (16.1, . . . , 16.4) into the third substrate (7) for separating the frame (1) from the movable structure (3.1, 3.2).

17. Method according to claim 13, comprising the step of etching an inclined section of the peripheral face (18) of the second substrate (6).

18. Method according to claim 17, comprising the step depositing a metal layer (19) connecting the inclined peripheral face and the frame (1).

19. Method according to claim 18, comprising the step of bonding the frame (1) and the second substrate (6) at their mating main surfaces by an insulating bonding (9) material.
